(19) United States
(12) Patent Application Publication
(10) Pub. No.: US 2004/0159924 A1
(43) Pub. Date: Aug. 19, 2004

(54) Semiconductor device

(75) Inventors: Shigeo Tokumitsu, Hyogo (JP); Satoshi Shimizu, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/627,606

(22) Filed: Jul. 28, 2003

(30) Foreign Application Priority Data
Feb. 18, 2003 (JP) 2003-039254(P)

(51) Int. Cl. H01L 23/02

(52) U.S. Cl. 257/678

(57) ABSTRACT

A semiconductor chip is produced through dicing without removing a conductive film for forming an interconnection and the like from a dicing line region. A prescribed insulating sheet member is adhered to this semiconductor chip at its back face, and the back face and the side face of semiconductor chip, and part of a front face along the periphery of semiconductor chip are covered by insulating sheet member. Thus, even when the conductive film in the dicing line region is curled up by dicing and a burr is resulted at the periphery of semiconductor chip, burr is covered by insulating sheet member to prevent a wire and burr from directly contacting to each other. Thus, a semiconductor device in which an electrical short circuit is prevented without removing a conductive film from a dicing line can be obtained.

### BACKGROUND OF THE INVENTION

1. Field of the Invention

The present invention relates to a semiconductor device, and more specifically, to a semiconductor device in which an electrical short circuit between a burr resulted from dicing and a wire is prevented.

2. Description of the Background Art

When manufacturing a semiconductor device, first it undergoes prescribed processes as a semiconductor substrate (wafer) to have an element, an interconnection and the like to be formed on its surface. After finishing all the processes that should be done to a wafer, the wafer is diced along a dicing line into individual semiconductor chips.

Each semiconductor chip thus cut undergoes prescribed packaging processes including a prescribed die bonding step or wire bonding step to be finished as a semiconductor device.

When dicing a wafer along a dicing line, a conductive film in the dicing line region is curled up. Accordingly, there exists a problem that a wire and the conductive film thus curled up contact to each other when performing wire bonding to establish an electrical short circuit.

To solve such a problem, a method for removing a conductive film in a dicing line region before performing a dicing process is proposed, for example in Japanese Patent Laying-Open Nos. 10-154670 and 11-204525.

By removing a conductive film in a dicing line region before dicing a wafer, a curled up conductive film will not present on the wafer. As a result, an electrical short circuit is prevented, which would otherwise be established between a wire and the curled up conductive film.

However, the semiconductor device manufacturing method above involves a problem that an additional process is required for removing a conductive film from a dicing line region of a wafer.

### SUMMARY OF THE INVENTION

The present invention is to solve the problem above, and the object of the present invention is to provide a semiconductor device in which electrical short circuit is prevented without removing a conductive film from a dicing line region.

A semiconductor device according to the present invention includes a semiconductor chip, an insulating sheet member, and a conductive wire. The semiconductor chip is diced from a semiconductor substrate with a prescribed element and an electrode portion formed on its main face and without removing a conductive film from a dicing line region. The conductive wire is connected to the electrode portion. The insulating sheet member covers part of the conductive film along periphery of the semiconductor chip.

According to a semiconductor device of the present invention, a semiconductor chip is diced without removing a conductive film from a dicing line region, and part of the conductive film along the periphery of the semiconductor chip is covered by an insulating sheet member. Thus, the conductive wire connected to the electrode portion and conductive film along the periphery will not directly connect to each other, and an electrical short circuit in the semiconductor device can be prevented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing one step of a semiconductor device manufacturing method according to a first embodiment of the present invention;

FIG. 2 is a partial cross-sectional view showing the step of FIG. 1 according to the first embodiment of the present invention;

FIG. 3 is a perspective view showing one step that follows the step of FIG. 1 according to the first embodiment of the present invention;

FIG. 4 is a partial cross-sectional view showing the step of FIG. 3 according to the first embodiment of the present invention;

FIG. 5 is a perspective view showing one step that follows the step of FIG. 3 according to the first embodiment of the present invention;

FIG. 6 is a partial cross-sectional view showing the step of FIG. 5 according to the first embodiment of the present invention;

FIG. 7 is a partial cross-sectional view showing one step that follows the step of FIG. 5 according to the first embodiment of the present invention;

FIG. 8 is a perspective view showing one step of a semiconductor device manufacturing method according to a second embodiment of the present invention;

FIG. 9 is a partial cross-sectional view showing the step of FIG. 8 according to the second embodiment of the present invention;

FIG. 10 is a perspective view showing one step that follows the step of FIG. 8 according to the second embodiment of the present invention;

FIG. 11 is a partial cross-sectional view showing the step of FIG. 10 according to the second embodiment of the present invention;

FIG. 12 is a partial cross-sectional view showing one step that follows the step of FIG. 11 according to the second embodiment of the present invention;

FIG. 13 is a partial cross-sectional view showing one step that follows the step of FIG. 12 according to the second embodiment of the present invention;

FIG. 14 is a partial cross-sectional view showing one step that follows the step of FIG. 13 according to the second embodiment of the present invention;

FIG. 15 is a cross-sectional view showing one modification of a semiconductor device according to each embodiment of the present invention; and

FIG. 16 is a cross-sectional view showing other modification of a semiconductor device according to each embodiment of the present invention.

### DESCRIPTION OF THE PREFERRED EMBODIMENTS

### First Embodiment

Now, description is given on a semiconductor device manufacturing method and a semiconductor device manufactured from the method according to a first embodiment of the present invention.

First, a process which should be provided to a wafer for forming a prescribed element, an interconnection and the like thereon is completed. At this point, a conductive film for forming an interconnection and the like is not removed and remained in a dicing line region on the wafer.

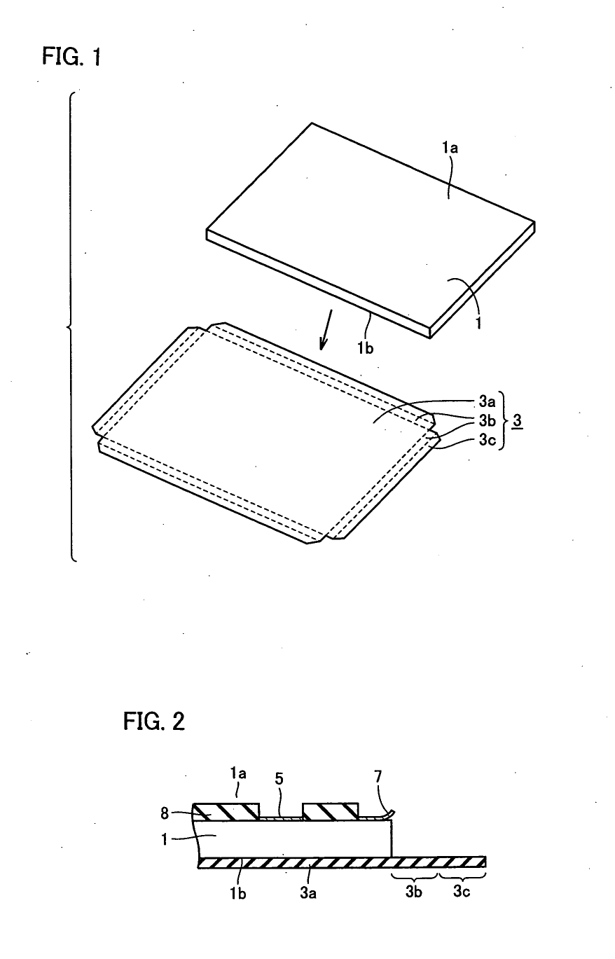

By dicing the wafer, a semiconductor chip 1 is cut as shown in FIG. 1. As shown in FIG. 2, a surface 1a of semiconductor chip 1 is covered by a passivation film 8, while exposing electrode portion 5 as a so-called bonding pad at the part to be connected to a wire.

Further, at the periphery of semiconductor chip 1, a curled up portion (burr) 7 resulted from dicing the conductive film remained in the dicing line region is present. Note that the conductive film is a film for forming electrode portion 5 or an interconnection (not shown).

Then, as shown in FIG. 1, an insulating sheet member 3 is prepared for adhering to semiconductor chip 1 to cover a prescribed portion of semiconductor chip 1. As a material of insulating sheet member 3, a resin base sheet member or a rubber base sheet member can be employed.

In this case, insulating sheet member 3 is provided with a first adhering portion 3a for adhering to a back face 1b of semiconductor chip 1, a second adhering portion 3b for adhering to a side face of semiconductor chip 1, a third adhering portion 3c for adhering to part of a front face 1a along the periphery of semiconductor chip 1.

Note that the side face of semiconductor chip 1 is a cross section of a wafer resulted from dicing the wafer.

Next, as shown in FIGS. 1 and 2, only first adhering portion 3a of insulating sheet member 3 is adhered to back face 1b of semiconductor chip 1, while second adhering portion 3b and third adhering portion 3c are remained in the same state.

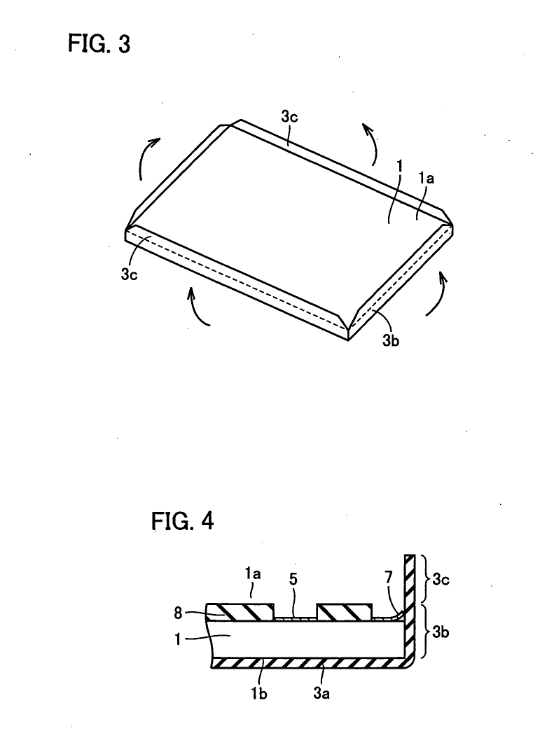

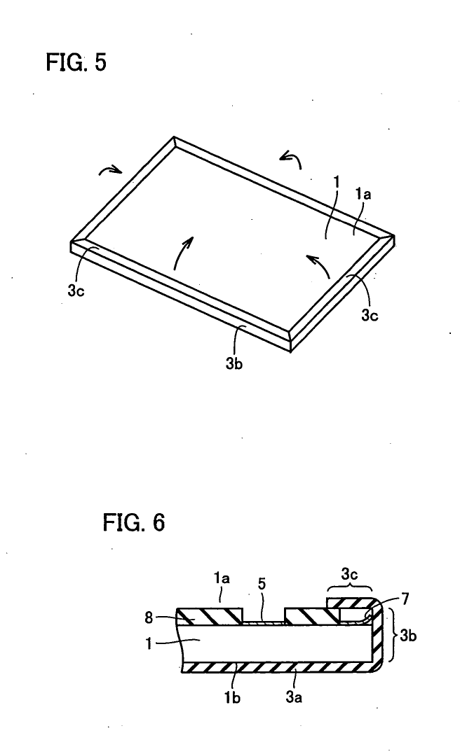

Next, as shown in FIGS. 3 and 4, second adhering portion 3b of insulating sheet member 3 is adhered to the side face of semiconductor chip 1. Then, as shown in FIGS. 5 and 6, third adhering portion 3c of insulating sheet member 3 is adhered to part of front face 1a along the periphery of semiconductor chip 1.

Thus, burr 7 that is curled up and remained on the periphery of semiconductor chip 1 is covered by second adhering portion 3b and third adhering portion 3c of insulating sheet member 3.

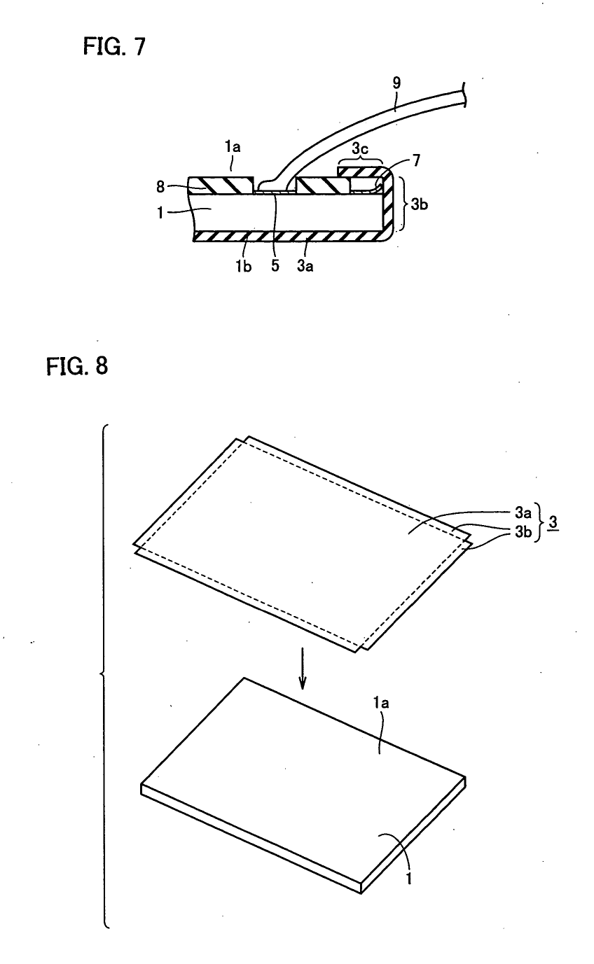

Next, as shown in FIG. 7, a wire 9 is bonded to electrode portion 5 provided on the front face of semiconductor chip 1, and electrode portion 5 and a prescribed lead frame (not shown) are electrically connected to each other. Thereafter, semiconductor chip 1 is sealed in a prescribed package (not shown) to be finished as a semiconductor device.

In the semiconductor manufacturing method described above, first, wafer is diced into semiconductor chip 1 without removing the conductive film for forming an interconnection and the like from its dicing line region.

Then, prescribed insulating sheet member 3 is adhered to back face 1b of semiconductor chip 1 thus cut, and the back face, the side face and part of front face 1a along the periphery of semiconductor chip 1 are covered by insulating sheet member 3.

Therefore, even when the conductive film remained in the dicing line region is curled up by dicing and burr 7 is formed in the periphery of semiconductor chip 1, burr 7 is covered by insulating sheet member 3. Accordingly, wire 9 and burr 7 will not directly contact to each other after wire 9 is bonded to electrode portion 5.

As a result, in a semiconductor device, for example one wire and another wire are prevented from electrically connecting to each other via burr 7 to establish an electrical short circuit. Thus, the reliability of a semiconductor device can be improved.

### Second Embodiment

In the following, description is given on a semiconductor manufacturing method and a semiconductor device manufactured from the method according to a second embodiment of the present invention.

First, as shown in FIG. 8, similarly to the manufacturing method above, a wafer is diced into semiconductor chip 1 without removing a conductive film for forming an interconnection and the like from a dicing line region.

Then, as shown in FIG. 8, a sheet-like insulating sheet member 3 is prepared for adhering to semiconductor chip 1 to cover a prescribed portion of semiconductor chip 1. As a material of insulating sheet member 3, a resin base sheet member or a rubber base sheet member can be employed, which preferably is meltable by soldering in wire bonding as will be described later.

In this case, insulating sheet member 3 is provided with first adhering portion 3a for adhering to a front face 1a of semiconductor chip 1, and second adhering portion 3b for adhering to the side face of semiconductor chip 1.

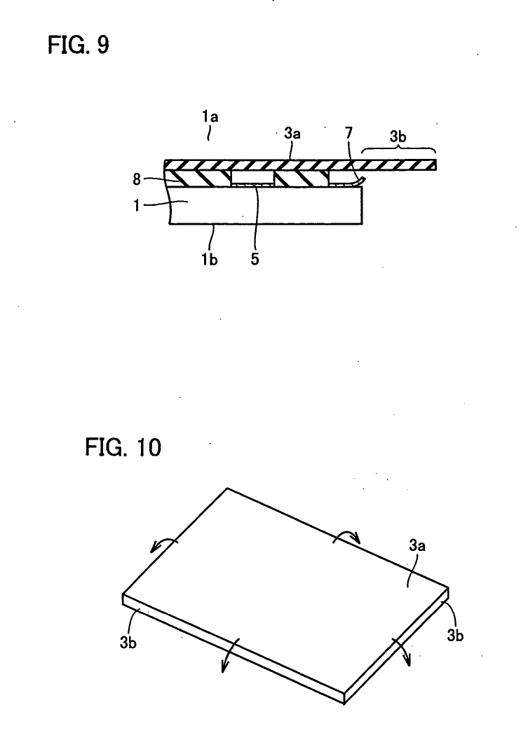

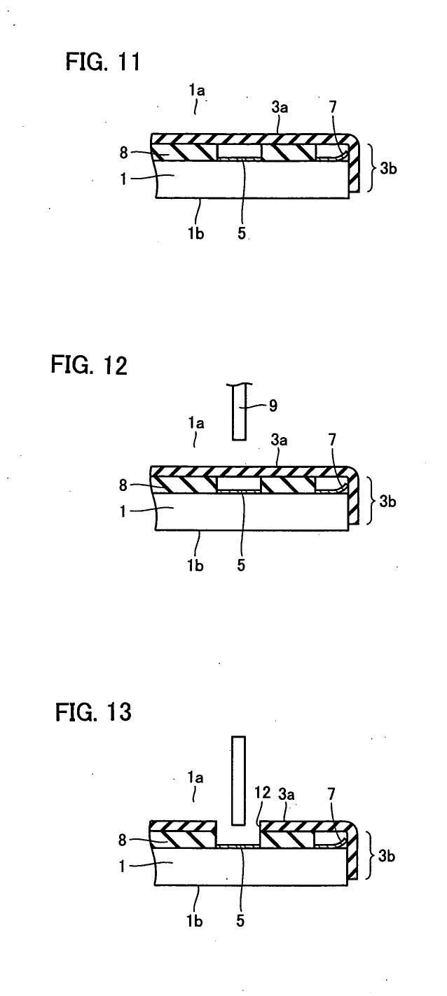

Next, as shown in FIGS. 8 and 9, only first adhering portion 3a of insulating sheet member 3 is adhered to front face 1a of semiconductor chip 1, while second adhering portion 3b is remained in the same state. Then, as shown in FIGS. 10 and 11, second adhering portion 3b of insulating sheet member 3 is adhered to the side face of semiconductor chip 1.

Thus, burr 7 that is curled up and remained on the periphery of semiconductor chip 1 is covered by first adhering portion 3a and second adhering portion 3b of insulating sheet member 3.

Next, as shown in FIG. 12, in order to bond wire 9 to electrode portion 5, the tip of wire 9 is arranged immediately above electrode portion 5. Then, as shown in FIG. 13, by the heat generated from soldering wire 9 and electrode portion 5, part of insulating sheet member 3 that is positioned immediately above electrode portion 5 is torn or melted, and an opening 12 is formed.

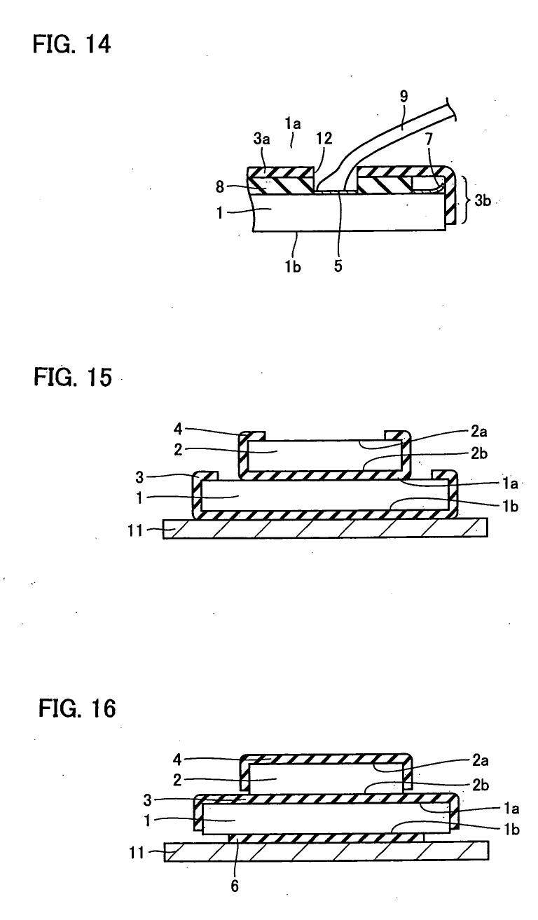

Next, as shown in FIG. 14, through opening 12 formed in insulating sheet member 3, wire 9 is bonded to electrode portion 5, and electrode portion 5 and a prescribed lead frame (not shown) are electrically connected to each other. Thereafter, semiconductor chip 1 is sealed in a prescribed package (not shown) to be finished as a semiconductor device.

In the semiconductor manufacturing method described above, similarly to the manufacturing method of the first embodiment, a wafer is diced into semiconductor chip 1 without removing the conductive film for forming an interconnection and the like from its dicing line region.

Then, a prescribed insulating sheet member 3 is adhered to front face 1a of semiconductor chip 1 thus cut, and the front face and the side face are covered by insulating sheet member 3.

Therefore, even when the conductive film remained in the dicing line region is curled up by dicing and burr 7 is formed in the periphery of semiconductor chip 1, burr 7 is covered by insulating sheet member 3. Accordingly, wire 9 and burr 7 will not directly contact to each other after wire 9 is bonded to electrode portion 5.

As a result, in a semiconductor device, for example one wire and another wire is prevented from electrically connecting to each other via burr 7 to establish an electrical short circuit. Thus, the reliability of a semiconductor device can be improved.

In accordance with the recent development of mobile equipment, a package of a semiconductor element (semiconductor chip) is required to be compact and thin. To meet with the requirement, an arrangement is proposed, in which a plurality of semiconductor chips are polished to reduce their thickness and then layered.

Accordingly, as one modification, description is given on a semiconductor device with layered semiconductor chips where the insulating sheet member described in the first embodiment is adhered to each of the semiconductor chips.

As shown in FIG. 15, in a semiconductor device according to one modification, one semiconductor chip 1 with insulating sheet member 3 adhered to its back face 1b is fixed on a front face of a die pad 11.

Then, another semiconductor chip 2 with insulating sheet member 4 adhered to its back face 2b is fixed on front face 1a of one semiconductor chip 1.

Next, as other modification, description is given on a semiconductor device with layered semiconductor chips where the insulating sheet member described in the second embodiment is adhered to each of the semiconductor chips.

As shown in FIG. 16, in a semiconductor device according to other modification, one semiconductor chip 1 with insulating sheet member 3 adhered to its front face 1a is fixed on the front face of die pad 11 with an insulating sheet member 6 between them.

Then, another semiconductor chip 2 with insulating sheet member 4 adhered to its front face 2a is fixed on insulating sheet member 3 that covers front face 1a of one semiconductor chip 1.

As above, in a semiconductor device according to each modification, by layering semiconductor chips 1, 2 polished to be thin and having insulating sheet member 3, 4 adhered thereto, respectively, the semiconductor device can be made compact and thin.

In special, the semiconductor device according to the other modification shown in FIG. 16 requires additional insulating sheet member 6 for fixing one semiconductor chip 1 on die pad 11, whereas the semiconductor device according to the one modification shown in FIG. 15 does not require such an insulating sheet member.

As a result, the semiconductor device according to the one modification requires fewer insulating sheet members as compared to the semiconductor device according to the other modification.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor chip diced from a semiconductor substrate with a prescribed element and an electrode portion formed on its main face and without removing a conductive film from a dicing line region;
a conductive wire connected to said electrode portion; and
an insulating sheet member for covering part of said conductive film along periphery of said semiconductor chip.

2. The semiconductor device according to claim 1, wherein
said insulating sheet member is provided for covering a back face of said semiconductor chip, a side face of said semiconductor chip, and part of the front face along periphery of said semiconductor chip.

3. The semiconductor device according to claim 2 comprising
a plurality of said semiconductor chips covered by said insulating sheet member, wherein said plurality of semiconductor chips are layered.

4. The semiconductor device according to claim 1, wherein
said insulating sheet member is provided for covering the front face of said semiconductor chip and a side face of said semiconductor chip.

5. The semiconductor device according to claim 4 further comprising
an opening formed in said insulating sheet member at a position corresponding to said electrode portion, wherein said conductive wire is connected to said electrode portion through said opening.

6. The semiconductor device according to claim 5 comprising
a plurality of said semiconductor chips covered by said insulating sheet member, wherein said plurality of semiconductor chips are layered.

7. The semiconductor device according to claim 4 comprising
a plurality of said semiconductor chips covered by said insulating sheet member, wherein said plurality of semiconductor chips are layered.

8. The semiconductor device according to claim 1 comprising
a plurality of said semiconductor chips covered by said insulating sheet member, wherein said plurality of semiconductor chips are layered.
